(19) United States
(12) Patent Application Publication
(10) Pub. No.: US 2013/0333752 A1
(43) Pub. Date: Dec. 19, 2013

(54) Photovoltaic Solar Cell With High-Haze Substrate

(71) Applicant: PPG INDUSTRIES OHIO, INC., Cleveland, OH (US)

(72) Inventor: Songwei Lu, Wexford, PA (US)

(73) Assignee: PPG INDUSTRIES OHIO, INC., Cleveland, OH (US)

(21) Appl. No.: 13/678,631

(22) Filed: Nov. 16, 2012

Related U.S. Application Data
(63) Continuation of application No. 12/643,448, filed on Dec. 21, 2009.
Application No. 12/643,448 is a continuation-in-part of application No. 13/364,898, filed on Feb. 2, 2012.
(60) Provisional application No. 61/440,588, filed on Feb. 8, 2011.

(51) Int. Cl. H01L 31/0216

(52) U.S. Cl. CPC H01L 31/02168
USPC 136/256; 438/69

(57) ABSTRACT

A solar cell includes a first substrate having a first surface and a second surface. A haze coating is provided over at least a portion of the first surface, the haze coating comprising an oxide coating incorporating nanoparticles. A first conductive layer is provided over at least a portion of the second surface. A semiconductor layer is provided over the first conductive layer. A second conductive layer is provided over at least a portion of the semiconductor layer.

### CROSS REFERENCE TO RELATED APPLICATIONS

This application is a continuation-in-part of U.S. application Ser. No. 12/643,448, filed Dec. 21, 2009, herein incorporated by reference in its entirety. This application also is a continuation-in-part of U.S. application Ser. No. 13/364,898, filed Feb. 2, 2012, which claimed priority to U.S. Provisional Application No. 61/440,588, filed Feb. 8, 2011, which applications also are herein incorporated by reference in their entirety.

### BACKGROUND OF THE INVENTION

1. Field of the Invention

This invention relates generally to solar cells, e.g., photovoltaic (PV) cells and, more particularly, to a solar cell substrate having increased light scattering for improved light utilization.

2. Technical Considerations

A solar cell or photovoltaic (PV) cell is an electronic device that directly converts sunlight into electricity. Light shining on the solar cell produces both a current and a voltage to generate electric power. In a solar cell, photons from sunlight hit the solar cell and are adsorbed by a semiconducting material. Electrons are knocked loose from their atoms, causing an electric potential difference. Current starts flowing through the material to cancel the potential difference. Due to the special composition of solar cells, the electrons are only allowed to move in a single direction.

A conventional amorphous silicon thin film solar cell typically includes a glass substrate (cover plate) over which is provided a transparent conductive oxide (TCO) contact layer and an amorphous silicon thin film active layer having a p-n junction. A rear metallic layer acts as a reflector and back contact. The TCO has an irregular surface to increase light scattering. In solar cells, light scattering or “haze” is used to trap light in the active region of the cell. The more light that is trapped in the cell, the higher the efficiency that can be obtained. However, the haze cannot be so great as to adversely impact upon the transparency of light through the TCO. Therefore, light trapping is an important issue when trying to improve the efficiency of solar cells and is particularly important in thin film cell design. However, with thin film devices, this light trapping is more difficult because the layer thicknesses are much thinner than those in previously known monocrystalline devices. As the film thicknesses are reduced, they tend toward coatings having predominantly parallel surfaces. Such parallel surfaces typically do not provide significant light scattering. It is also desirable if the conductive film is highly transparent to permit the maximum amount of solar radiation to pass to the silicon layer. As a general rule, the more photons that arrive at the semiconductor material, the higher the efficiency of the cell. Therefore, it is desirable that as large a number of photons as possible reach the semiconductor material. It also would be desirable to provide a solar cell with a substrate (e.g., cover plate) having increased haze to trap or redirect photons to the semiconductor material.

### SUMMARY OF THE INVENTION

A solar cell comprises a first substrate having a first surface and a second surface. A haze coating is located over at least a portion of the first surface. The haze coating comprises an oxide coating incorporating nanoparticles. A first conductive layer is located over at least a portion of the second surface. A semiconductor layer is located over the first conductive layer. A second conductive layer is located over at least a portion of the semiconductor layer.

Another solar cell comprises a first float glass substrate having a tin side and an air side. A haze coating is located over at least a portion of the tin side. The haze coating comprises silica incorporating nanoparticles selected from the group consisting of nanoparticles of titania, indium tin oxide, fluorine tin oxide, silica, alumina, colloidal silica, cerium oxide, and mixtures thereof. A first conductive layer is located over at least a portion of the air side. The first conductive layer comprises oxides of one or more of Sn and In. A semiconductor layer is located over the first conductive layer. The semiconductor layer comprises a material selected from the group consisting of monocrystalline silicon, polycrystalline silicon, amorphous silicon, cadmium telluride, and copper indium celenide/sulfide. A second conductive layer is located over at least a portion of the semiconductor layer. The second conductive layer comprises oxides of one or more of Sn and In.

A method of making a solar cell comprises providing a haze coating over at least a portion of a tin side of a float glass substrate. The haze coating comprises silica incorporating nanoparticles selected from the group consisting of nanoparticles of titania, indium tin oxide, fluorine tin oxide, silica, alumina, colloidal silica, cerium oxide, and mixtures thereof. A first conductive layer is provided over at least a portion of an air side of the float glass substrate. The first conductive layer comprises oxides of one or more of Sn and In. A semiconductor layer is provided over the first conductive layer. The semiconductor layer comprises a material selected from the group consisting of monocrystalline silicon, polycrystalline silicon, amorphous silicon, cadmium telluride, and copper indium celenide/sulfide. A second conductive layer is provided over at least a portion of the semiconductor layer. The second conductive layer comprises oxides of one or more of Sn and In.

### BRIEF DESCRIPTION OF THE DRAWINGS

A complete understanding of the invention will be obtained from the following description when taken in connection with the accompanying drawing figures.

FIG. 1 is a side, sectional view (not to scale) of a solar cell incorporating an undercoating of the invention and a coated substrate of the invention; and

FIG. 2 is a side, sectional view (not to scale) of another coated article having an undercoating of the invention.

### DESCRIPTION OF THE PREFERRED EMBODIMENTS

As used herein, spatial or directional terms, such as “left”, “right”, “inner”, “outer”, “above”, “below”, and the like, relate to the invention as it is shown in the drawing figures. However, it is to be understood that the invention can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims may vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. Further, as used herein, the terms “formed over”, “deposited over”, “provided over”, or “located over” mean formed, deposited, provided, or located on a surface but not necessarily in direct contact with the surface. For example, a coating layer “formed over” a substrate does not preclude the presence of one or more other coating layers or films of the same or different composition located between the formed coating layer and the substrate. As used herein, the terms “polymer” or “polymeric” include oligomers, homopolymers, copolymers, and terpolymers, e.g., polymers formed from two or more types of monomers or polymers. The terms “visible region” or“visible light” refer to electromagnetic radiation having a wavelength in the range of 380 nm to 760 nm. The terms “infrared region” or “infrared radiation” refer to electromagnetic radiation having a wavelength in the range of greater than 760 nm to 100,000 nm. The terms “ultraviolet region” or “ultraviolet radiation” mean electromagnetic energy having a wavelength in the range of 200 nm to less than 380 nm. The terms “microwave region” or ‘Microwave radiation” refer to electromagnetic radiation having a frequency in the range of 300 megahertz to 300 gigahertz. Additionally, all documents, such as, but not limited to, issued patents and patent applications, referred to herein are to be considered to be “incorporated by reference” in their entirety. In the following discussion, the refractive index values are those for a reference wavelength of 550 nanometers (nm). The term “film” refers to a region of a coating having a desired or selected composition. A “layer” comprises one or more “films”. A “coating” or “coating stack” is comprised of one or more “layers”.

Although the coated substrate incorporating the high-haze coating of the invention will be described with respect to use in a solar cell, it is to be understood that the coated substrate is not limited to use with solar cells but could be used in other applications, such as architectural glazings, organic light-emitting diodes, or solar control transparencies.

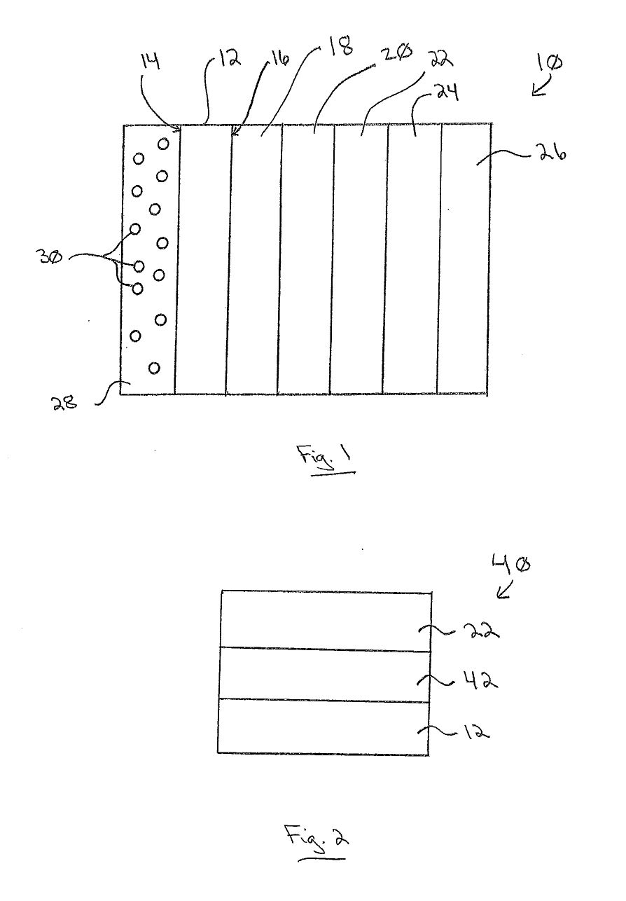

An exemplary solar cell 10 incorporating features of the invention is shown in FIG. 1. The solar cell 10 includes a first (outer) substrate 12 having a first (outer) major surface 14 and a second (inner) major surface 16. By “outer” is meant the surface facing the incident radiation, e.g., sunlight. An optional undercoating 18 may be located over the second surface 16. A first conductive layer 20 is located over the second surface 16 (such as on the undercoating 18, if present). The first conductive layer 20 can be, for example, a transparent conductive oxide (TCO) coating. A semiconductor layer 22 is located over the first conductive layer 20. A second conductive layer 24 is located over the semiconductor layer 22. For example, the second conductive layer 24 can be a metal layer or a metal-containing layer. An optional second (inner) substrate 26 is located over the second conductive layer 24. However, unlike conventional solar cells, the solar cell 10 includes a haze coating 28 over the outer surface 14 of the outer substrate 12. The haze coating 28 incorporates nanoparticles 30.

In the broad practice of the invention, the first substrate 12 (and optional second substrate 26, if present) can include any desired material having any desired characteristics. For example, the first substrate 12 can be transparent or translucent to visible light. By “transparent” is meant having a visible light transmittance of greater than 0% up to 100%. Alternatively, the first substrate 12 can be translucent. By “translucent” is meant allowing electromagnetic energy (e.g., visible light) to pass through but diffusing this energy such that objects on the side opposite the viewer are not clearly visible. Examples of suitable materials include, but are not limited to, plastic substrates (such as acrylic polymers, such as polyacrylates; polyalkylmethacrylates, such as polymethylmethacrylates, polyethylmethacrylates, polypropylmethacrylates, and the like; polyurethanes; polycarbonates; polyalkylterephthalates, such as polyethyleneterephthalate (PET), polypropyleneterephthalates, polybutyleneterephthalates, and the like; polysiloxane-containing polymers; or copolymers of any monomers for preparing these, or any mixtures thereof); glass substrates; or mixtures or combinations of any of the above. For example, the first substrate 12 can include conventional soda-lime-silicate glass, borosilicate glass, or leaded glass. The glass can be clear glass. By “clear glass” is meant non-tinted or non-colored glass. Alternatively, the glass can be tinted or otherwise colored glass. The glass can be annealed or heat-treated glass. As used herein, the term “heat treated” means tempered or at least partially tempered. The glass can be of any type, such as conventional float glass, and can be of any composition having any optical properties, e.g., any value of visible transmission, ultraviolet transmission, infrared transmission, and/or total solar energy transmission. By “float glass” is meant glass formed by a conventional float process in which molten glass is deposited onto a molten metal bath, such as molten tin. The bottom side of the glass, i.e., the side that was in contact with the molten tin bath, conventionally is referred to as the “tin side” and the top side of the glass conventionally is referred to as the “air side”. The tin side of the glass can have small amounts of tin incorporated into the glass surface. Although not limiting to the invention, examples of glass suitable for the substrate are described in U.S. Pat. Nos. 4,746,347; 4,792,536; 5,030,593; 5,030,594; 5,240,886; 5,385,872; and 5,393,593. Non-limiting examples of glass that can be used for the practice of the invention include Solargreen®, Solextra®, GL-20®, GL35™, Solarbronze®, Starphire®, Solarphire®, Solarphire PV® and Solargray® glass, all commercially available from PPG Industries Inc. of Pittsburgh, Pa.

The first substrate 12 can be of any desired dimensions, e.g., length, width, shape, or thickness. For example, the first substrate 12 can be planar, curved, or have both planar and curved portions. In one non-limiting embodiment, the first substrate 12 can have a thickness in the range of 0.5 mm to 10 mm, such as 1 mm to 5 mm, such as 2 mm to 4 mm, such as 3 mm to 4 mm.

The first substrate 12 can have a high visible light transmission at a reference wavelength of 550 nanometers (nm). By “high visible light transmission” is meant visible light transmission at 550 nm of greater than or equal to 85%, such as greater than or equal to 87%, such as greater than or equal to 90%, such as greater than or equal to 91%, such as greater than or equal to 92%.

The optional undercoating 18, if present, can be a multilayer coating having two or more coating layers, such as a first layer and a second layer, with the second layer over the first layer. The first layer can provide a barrier between the first substrate 12 and the overlying coating layers. Silica is known to provide good barrier properties, particularly as a barrier to sodium ion diffusion out of a glass substrate. However, silica presents deposition difficulties. In one practice of the invention, the first layer is an oxide of at least one material selected from tin or titanium. For example, the first layer can be a tin oxide layer having a thickness of less than 50 nm, such as less than 40 nm, such as less than 30 nm, such as less than 25 nm, such as less than 20 nm, such as less than 15 nm, such as in the range of 5 nm to 25 nm, such as in the range of 5 nm to 15 nm. In another embodiment, the first layer is titania having a thickness of less than 30 nm, such as less than 25 nm, such as less than 20 nm, such as less than 15 nm, such as in the range of 5 nm to 25 nm, such as in the range of 5 nm to 15 nm, such as in the range of 10 nm to 15 nm.

The second layer comprises a mixture of two or more oxides selected from oxides of silicon, titanium, aluminum, tin, zirconium and/or phosphorus. The oxides can be present in any desired proportions. The second layer can be a homogeneous coating. Alternatively, the second layer can be a gradient coating with the relative proportions of at least two of the constituents varying through the coating. Alternatively, the second layer can be formed by two or more separate coating layers, e.g., each layer being formed from one or more of the oxide constituents. For example, for a second layer comprising oxides of silicon, tin, and phosphorous, each of these oxide layers can be deposited as a separate layer, or two of the oxides can be deposited in one layer and the other oxide in another adjacent layer.

As discussed above, the second layer can include mixtures of at least two oxides having elements selected from silicon, titanium, aluminum, tin, zirconium, and/or phosphorus. Such mixtures include, but are not limited to, titania and phosphorous oxide; silica and alumina; titania and alumina; silica and phosphorous oxide; titania and phosphorous oxide; silica and tin oxide, tin oxide and phosphorous oxide, titania and tin oxide, alumina and tin oxide, silica and zirconia; titania and zirconia; alumina and zirconia; alumina and phosphorous oxide; zirconia and phosphorous oxide; or any combination of the above materials. The relative proportions of the oxides can be present in any desired amount, such as 0.1 wt. % to 99.9 wt. % of one material and 99.9 wt. % to 0.1 wt. % of the other material.

Additionally, the second layer can include mixtures of at least three oxides, such as but not limited to, three or more oxides having elements selected from silicon, titanium, aluminum, tin, zirconium and/or phosphorus. Examples include, but are not limited to, mixtures comprising silica, titania, and phosphorous oxide; silica, tin oxide, and phosphorus oxide; silica, titania, and alumina; and silica, titania and zirconia. For example, the second layer can comprise a mixture of silica and titania, with at least one other oxide selected from alumina, zirconia, and phosphorous oxide. For another example, the second layer can comprise a mixture of silica and tin oxide, with at least one other oxide selected from alumina, zirconia, and phosphorous oxide. In a further example, the second layer can comprise a mixture of silica and phosphorous oxide, with at least one other oxide selected from tin oxide and titania. The relative proportions of the oxides can be present in any desired amount, such as 0.1 wt. % to 99.9 wt. % of one material, 99.9 wt. % to 0.1 wt. % of a second material, and 0.1 wt. % to 99.9 wt. % of a third material.

One exemplary second layer comprises a mixture of silica, titania, and phosphorous oxide. The silica can be present in the range of 30 volume percent (vol. %) to 80 vol. %. The titania can be present in the range of 5 vol. % to 69 vol. %. The phosphorous oxide can be present in the range of 1 vol. % to 15 vol. %. The second layer can comprise a mixture of silica, titania, and phosphorous oxide having less than 40 mole percent titania, such as less than 30 mole percent titania, such as less than 25 mole percent titania, such as less than 20 mole percent titania.

Another exemplary second layer comprises a mixture of silica, tin oxide, and phosphorous oxide. The silica can be present in the range of 30 volume percent (vol. %) to 80 vol. %. The tin oxide can be present in the range of 5 vol. % to 69 vol. %. The phosphorous oxide can be present in the range of 1 vol. % to 15 vol. %. The second layer can comprise a mixture of silica, tin oxide, and phosphorous oxide having less than 50 mole percent tin oxide, such as less than 40 mole percent tin oxide, such as less than 30 mole percent tin oxide, such as less than 20 mole percent tin oxide, such as less than 15 mole percent tin oxide, such as in the range of 15 mole percent to 40 mole percent tin oxide, such as 15 mole percent to 20 mole percent tin oxide.

The second layer can have any desired thickness, such as but not limited to, 10 nm to 100 nm, such as 10 nm to 80 nm, such as 10 nm to 60 nm, such as 10 nm to 40 nm, such as 20 nm to 40 nm, such as 20 nm to 35 nm, such as 20 nm to 30 nm, such as 25 nm.

The first conductive (TCO) layer 20 comprises at least one conductive oxide layer, such as a doped oxide layer. For example, the TCO layer 20 can include one or more oxide materials, such as but not limited to, one or more oxides of one or more of Zn, Fe, Mn, Al, Ce, Sn, Sb, Hf, Zr, Ni, Zn, Bi, Ti, Co, Cr, Si or In or an alloy of two or more of these materials, such as zinc stannate. The TCO layer 20 can also include one or more dopant materials, such as but not limited to, F, In, Al, P, and/or Sb. In one non-limiting embodiment, the TCO layer 20 is a fluorine doped tin oxide coating, with the fluorine present h an amount less than 20 wt. % based on the total weight of the coating, such as less than 15 wt. %, such as less than 13 wt. %, such as less than 10 wt. %, such as less than 5 wt. %, such as less than 4 wt. %, such as less than 2 wt. %, such as less than 1 wt. %. The TCO layer 20 can be amorphous, crystalline, or at least partly crystalline.

The TCO layer 20 can have a thickness greater than 200 nm, such as greater than 250 nm, such as greater than 350 nm, such as greater than 380 nm, such as greater than 400 nm, such as greater than 420 nm, such as greater than 470 nm, such as greater than 500 nm, such as greater than 600 nm. In one non-limiting embodiment, the TCO layer 20 comprises fluorine doped tin oxide and has a thickness as described above, such as in the range of 350 nm to 1,000 nm, such as 400 nm to 800 nm, such as 500 nm to 700 nm, such as 600 nm to 700 nm, such as 650 nm.

The TCO layer 20 (e.g., fluorine doped tin oxide) can have a surface resistivity of less than 15 ohms per square (Ω/□), such as less than 14 Ω/□, such as less than 13.5 Ω/□, such as less than 13 Ω/□, such as less than 12 Ω/□, such as less than 11 Ω/□, such as less than 10 Ω/□.

The TCO layer 20 can have a surface roughness (RMS) in the range of 5 nm to 60 nm, such as 5 nm to 40 nm, such as 5 nm to 30 nm, such as 10 nm to 30 nm, such as 10 nm to 20 nm, such as 10 nm to 15 nm, such as 11 nm to 15 nm. The surface roughness of the first undercoating layer will be less than the surface roughness of the TCO layer 20.

The semiconductor layer 22 can be any conventional solar cell semiconductor material, such as crystalline silicon. Examples include monocrystalline silicon, polycrystalline silicon, and amorphous silicon. Other examples of semiconductor material include cadmium telluride and copper indium celenide/sulfide. In a typical silicon solar cell, a layer of phosphorous-doped (n-type) silicon is on top of a thicker boron-doped (p-type) silicon. An electrical field is created at the small p-n junction resulting in a flow of current when the cell is connected to an electrical load. An amorphous silicon layer 22 can have a thickness in the range of 200 nm to 1,000 nm, such as 200 nm to 800 nm, such as 300 nm to 500 nm, such as 300 nm to 400 nm, such as 350 nm.

The second conductive layer 24 can be a metallic layer or a metal containing layer and can include one or more metal oxide materials. Examples of suitable metal oxide materials include, but are not limited to, oxides of one or more of Zn, Fe, Mn, Al, Ce, Sn, Sb, Hf, Zr, Ni, Zn, Bi, Ti, Co, Cr, Si or In or an alloy of two or more of these materials, such as zinc stannate. The metal containing layer 24 can have a thickness in the range of 50 nm to 500 nm, such as 50 nm to 300 nm, such as 50 nm to 200 nm, such as 100 nm to 200 nm, such as 150 nm.

The optional second substrate 26, if present, can be of any material described above for the first substrate 12. The first substrate 12 and second substrate 26 can be of the same or different material and can be of the same or different thickness.

The haze coating 28 is formed on the outer surface 14 of the first substrate 12. For float glass substrates, the outer surface 14 can be the tin side of the glass and the inner surface 16 can be the air side of the glass. The haze coating 28 can be a metal oxide coating or a silica coating having nanoparticles 30 dispersed in the coating. Useful nanoparticles include, but are not limited to, titania, indium tin oxide, fluorine tin oxide, and silica (such as Ludox® colloidal silica commercially available from W. R. Grace & Co.)

The undercoating 18, first conductive layer 20, semiconductor layer 22, the second conductive layer 24, and the haze layer 28 can be formed over at least a portion of the substrate 12 by any conventional method, such as but not limited to, spray pyrolysis, chemical vapor deposition (CVD), or magnetron sputtered vacuum deposition (MSVD). The layers can all be formed by the same method or different layers can be formed by different methods. For example, the optional undercoating layer 18, first conductive layer 20, semiconductor layer 22, and second conductive layer 24 can be formed by CVD or MSVD, while the haze layer 28 is formed by spray pyrolysis.

In the spray pyrolysis method, a precursor composition having one or more oxide precursor materials, e.g., precursor materials for titania and/or silica and/or alumina and/or phosphorous oxide and/or zirconia, is carried in a suspension, e.g., an aqueous or non-aqueous solution, and is directed toward the surface of the substrate while the substrate is at a temperature high enough to cause the precursor composition to decompose and form a coating on the substrate. The composition can include one or more dopant materials. In a CVD method, a precursor composition is carried in a carrier gas, e.g., nitrogen gas, and is directed toward the heated substrate. In the MSVD method, one or more metal-containing cathode targets are sputtered under reduced pressure in an inert or oxygen-containing atmosphere to deposit a sputter coating over substrate. The substrate can be heated during or after coating to cause crystallization of the sputtered coating to form the coating.

In one non-limiting practice of the invention, one or more CVD coating apparatus can be employed at one or more positions in a conventional float glass ribbon manufacturing process. For example, CVD coating apparatus may be employed as the float glass ribbon travels through the tin bath, after it exits the tin bath, before it enters the annealing lehr, as it travels through the annealing lehr, or after it exits the annealing lehr. Because the CVD method can coat a moving float glass ribbon, yet withstand the harsh environments associated with manufacturing the float glass ribbon, the CVD method is particularly well suited to deposit coatings on the float glass ribbon in the molten tin bath. U.S. Pat. Nos. 4,853,257; 4,971,843; 5,536,718; 5,464,657; 5,714,199; and 5,599,387 describe CVD coating apparatus and methods that can be used in the practice of the invention to coat a float glass ribbon in a molten tin bath.

In one non-limiting embodiment, one or more CVD coaters can be located in the tin bath above the molten tin pool. As the float glass ribbon moves through the tin bath, the vaporized precursor composition can be added to a carrier gas and directed onto the top surface of the ribbon. The precursor composition decomposes to form a coating on the ribbon. The coating composition can be deposited on the ribbon at a location in which the temperature of the ribbon is less than 1300° F. (704° C.), such as less than 1250° F. (677° C.), such as less than 1200° F. (649° C.), such as less than 1190° F. (643° C.), such as less than 1150° F. (621° C.), such as less than 1130° F. (610° C.), such as in the range of 1190° F. to 1200° F. (643° C. to 649° C.). This is particularly useful in depositing a first conductive layer 20 (e.g., fluorine-doped tin oxide) having reduced surface resistivity since the lower the deposition temperature, the lower will be the resultant surface resistivity.

For example, to form a second undercoating layer comprising silica and titania, the composition comprises both a silica precursor and a titania precursor. One non-limiting example of a silica precursor is tetraethylorthosilicate (TEOS).

Examples of titania precursors include, but are not limited to, oxides, sub-oxides, or super-oxides of titanium. In one embodiment, the titania precursor material can include one or more titanium alkoxides, such as but not limited to, titanium methoxide, ethoxide, propoxide, butoxide, and the like; or isomers thereof, e.g., titanium isopropoxide, tetraethoxide, and the like. Exemplary precursor materials suitable for the practice of the invention include, but are not limited to, tetraisopropyltitanate (TPT). Alternatively, the titania precursor material can be titanium tetrachloride. Examples of alumina precursors include, but are not limited to, dimethylaluminumisopropoxide (DMAP) and aluminum tri-sec-butoxide (ATSB). The DMAP can be made by mixing trimethylaluminum and aluminumisopropoxide at a molar ratio of 2:1 in an inert atmosphere at room temperature. Examples of phosphorous oxide precursors include, but are not limited to, triethyl phosphite and triethyl phosphate. Examples of zirconia precursors include, but are not limited to, zirconium alkoxides.

A second undercoating layer having a combination of silica and titania provides advantages over previous oxide combinations. For example, the combination of a low refractive index material such as silica (refractive index of 1.5 at 550 nm) with a high refractive index material such as titania (refractive index of 2.48 for anatase titania at 550 nm) allows the refractive index of the first underlayer coating to be varied between these two extremes by varying the amount of silica and titania. This is particularly useful in providing the first undercoating layer with color or irridescence suppression properties.

However, the deposition rate of titania is typically much faster than that of silica. Under typical deposition conditions, this limits the amount of silica to no more than about 50 wt. %, which, in turn, limits the lower range of the refractive index of the resultant silica/titania coating. Therefore, a dopant material can be added to the silica and titania precursor composition to accelerate the deposition rate of silica. The dopant forms part of the resultant oxide mixture and, therefore, can be selected to provide enhanced performance properties to the resultant coating. Examples of dopants useful for the practice of the invention include, but are not limited to, materials containing one or more of phosphorous, aluminum, and zirconium to form oxides of these materials in the resultant coating. Examples of phosphorous oxide precursor materials include triethyl phosphite and triethyl phosphate. Examples of alumina precursor materials include aluminumtrisecbutoxide (ATSB) and dimethylaluminumisopropoxide (DMAP). Examples of zirconia precursors include zirconium alkoxide.

The haze coating 28 can be formed by spray pyrolysis. For example, a precursor composition for a desired oxide coating (such as silica) can be mixed with a precursor material for selected nanoparticles and the mixed coating spray applied to the heated outer surface 14 of the first substrate 12.

Another coated article 40 incorporating features of the invention is shown in FIG. 2. This article 40 is particularly useful for low emissivity or solar control applications. The article 40 includes a substrate 12, which can be as described above. A gradient dielectric layer 42 is formed over at least a portion of the substrate 12. A TCO layer 22, as described above, can be formed over at least a portion of the dielectric layer 42. The dielectric layer 42 can include a mixture of two or more oxides, for example three or more oxides, selected from oxides of silicon, titanium, aluminum, tin, zirconium, and/or phosphorus. In one example, the dielectric layer 42 comprises a mixture of silica, titania, and phosphorous oxide, with the proportion of silica varying through the layer 42 and being higher near the surface of the substrate 12 and lower at the outer surface of the layer 42. The proportion of titania could be lower near the surface of the substrate 12 and higher at the outer surface of the layer 42. The proportion of phosphorous oxide could be substantially the same throughout the layer 42 or could also be varied as the silica or titania.

### EXAMPLES

The following Examples are provided to illustrate various non-limiting aspects of the invention. However, it is to be understood that the invention is not limited to these specific Examples.

In the following Examples, the substrate (unless indicated to the contrary) is Solarphire® glass commercially available from PPG Industries, Inc. having a thickness of 2 millimeters (mm). The haze and transmittance values are percentage values and were measured using a Haze-Gard Plus hazemeter commercially available from BYK-Gardner USA. The temperature values are in degrees Fahrenheit (° F.) and the pressure values are in pounds per square inch (psi).

### Examples 1-3

### Relate to Various Undercoating Layers

### Prophetic Example 1

A coated article comprises a clear glass substrate having a thickness of 3.2 mm. A layer of tin oxide having a thickness of 15 nm is formed over the substrate surface. A dielectric layer of silica, tin oxide, and phosphorous oxide is formed over the layer of tin oxide and includes 1 mole % to 40 mole % tin oxide. The dielectric layer has a thickness of 20 nm to 40 nm. A layer of fluorine-doped tin oxide is formed over the dielectric layer and has a thickness of at least 470 nm. The coating layers are formed by CVD.

### Prophetic Example 2

A coated article comprises a clear glass substrate having a thickness of 3.2 mm. A layer of titania having a thickness of 10-15 nm is formed over the substrate surface. A dielectric layer of silica, titania, and phosphorous oxide is formed over the layer of titania and includes less than 25 mole % titania. The dielectric layer has a thickness of 20 nm to 40 nm. A layer of fluorine-doped tin oxide is formed over the dielectric layer and has a thickness of at least 470 nm. The coating layers are formed by CVD.

### Prophetic Example 3

A coated article comprises a clear glass substrate having a thickness of 3.2 mm. A layer of tin oxide having a thickness of 15 nm is formed over the substrate surface. A dielectric layer of silica, tin oxide, and phosphorous oxide is formed over the layer of tin oxide and includes 15 mole % to 20 mole % tin oxide. The dielectric layer has a thickness of 25 nm. A layer of fluorine-doped tin oxide is formed over the dielectric layer and has a thickness of 350 nm. The coating layers are formed by CVD.

### Examples 4-6

### Relate to Haze Coatings

### Example 4

This Example illustrates a substrate with a silica-haze layer incorporating titania nanoparticles on the tin side of the glass. TEOS means tetraethyl orthosilicate; TPT means titanium isopropoxide; DI water means deionized water; and IPA means isopropyl alcohol.

A first solution (as set forth in Table 1) and a second solution (as set forth in Table 2) were prepared. The TPT (titania nanoparlicle precursor) was added to adjust the refractive index of the coating.

TABLE 1
(SOLUTION 1)

| MATERIAL | AMT. (g) | PERCENT (%) |
|---|---|---|
| TPT | 50 | 24 |
| IPA | 50 | 24 |
| HNO₃ | 10 | 5 |
| DI Water | 100 | 48 |
| Total | 210 | 100 |

TABLE 2
(SOLUTION 2)

| MATERIAL | AMT. (g) | PERCENT (%) |
|---|---|---|
| TEOS | 80 | 21 |
| Ethanol | 280 | 72 |
| DI Water | 28 | 7 |
| Total | 388 | 100 |

These solutions were mixed in the proportions shown in Table 3 and Table 4 to form coating composition 1 (Table 3) and coating composition 2 (Table 4).

TABLE 3
(COATING 1)

| MATERIAL | AMT. (g) | PERCENT (%) |
|---|---|---|
| Solution 1 | 10 | 5 |
| Solution 2 | 190 | 95 |
| Total | 200 | 100 |

TABLE 4
(COATING 2)

| MATERIAL | AMT. (g) | PERCENT (%) |
|---|---|---|
| Solution 1 | 20 | 10 |
| Solution 2 | 180 | 90 |
| Total | 200 | 100 |

The coating compositions were spray applied onto a surface of oven heated glass substrates using a conventional spray coating device to form a haze coating of silica incorporating titania nanoparticles. As set forth in Table 5, the haze coating provided the substrate with haze greater than 10 percent while still maintaining transmittance greater than 90 percent.

TABLE 5

| | | | | AIR | | |
|---|---|---|---|---|---|---|
| | COATING | SPRAY | OVEN | PRESSURE | HAZE | TRANSMITTANCE |
| SAMPLE # | COMPOSITION | TIME (sec.) | TEMP ° F. | (psi) | (Post-Spray) | (Post-Spray) |
| 1 | 1 | 5 | 450 | 50 | 11.8 | 94.4 |
| 2 | 1 | 10 | 450 | 50 | 21.1 | 94.2 |
| 3 | 2 | 5 | 450 | 50 | 10.3 | 94.1 |
| 4 | 2 | 10 | 450 | 50 | 23.1 | 94.0 |

### Example 5

This Example illustrates a coated substrate with a haze layer of the invention on the tin side of the glass and a conductive layer (indium tin oxide layer) on the air side of the glass. A coating of indium tin oxide (ITO) was sputter deposited onto a major surface (air side) of a float glass substrate from an indium/tin cathode using a conventional magnetic sputter vapor deposition (MSVD) device. The ITO coating had a thickness of 300 nm. A haze layer (silica layer with titania nanoparticles) was applied by conventional spray pyrolysis onto the tin side of the glass substrate using the coating compositions described above. The spray parameters and optical results are shown in Table 6.

TABLE 6

| | | | | AIR | | | | |
|---|---|---|---|---|---|---|---|---|
| SAMPLE | COATING | SPRAY | OVEN | PRESSURE | HAZE | TRANSMITTANCE | HAZE | TRANSMITTANCE |
| # | COMPOSITION | TIME (sec.) | TEMP ° F. | (psi) | (Pre-Spray) | (Pre-Spray) | (Post-Spray) | (Post-Spray) |
| 5 | 1 | 5 | 450 | 50 | 0.14 | 86.9 | 11.8 | 87.2 |
| 6 | 2 | 10 | 450 | 50 | 0.12 | 87.5 | 19.7 | 87.6 |

### Example 6

This Example illustrates a substrate with a haze layer incorporating nanoparticles on one side of the substrate.

A third solution (as set forth in Table 7) and a fourth solution (as set forth in Table 8) were prepared.

TABLE 7
(Solution 3)

| MATERIAL | AMT. (g) | PERCENT |
|---|---|---|
| TPT | 151 | 24 |
| IPA | 151 | 24 |
| HNO₃ | 30 | 5 |
| DI Water | 303 | 48 |
| Total | 635 | 100 |

TABLE 8
(Solution 4)

| MATERIAL | AMT. (g) | PERCENT |
|---|---|---|
| TEOS | 300 | 32 |
| Ethanol | 525 | 56 |
| DI Water | 105 | 11 |
| Total | 930 | 100 |

These solutions were mixed in the proportions shown in Tables 9-11 to form Coating Compositions 3-5.

TABLE 9
(Coating 3)

| MATERIAL | AMT. (g) | PERCENT |
|---|---|---|
| Solution 3 | 22.5 | 10 |
| Solution 4 | 202.5 | 90 |

TABLE 10
(Coating 4)

| MATERIAL | AMT. | PERCENT |
|---|---|---|
| Solution 3 | 45 | 20 |
| Solution 4 | 180 | 80 |

TABLE 11
(Coating 5)

| MATERIAL | AMT. | PERCENT |
|---|---|---|
| Solution 3 | 58.5 | 30 |
| Solution 4 | 136.5 | 70 |

The coating compositions 3-5 were spray appled onto a surface (tin side) of oven heated glass substrates at 450° F. (232° C.) using a conventional spray coating device at an air pressure of 50 psi (344738 Pascal) to form a haze coating of silica incorporating titania nanoparticles.

Table 12 shows the average haze and transmittance values for the coated substrates.

TABLE 12

| | | AVERAGE | AVERAGE |
|---|---|---|---|
| SAMPLE | COATING | HAZE | TRANSMITTANCE |
| # | COMPOSITION | (POST-SPRAY) | (POST-SPRAY) |
| 7 | 3 | 63.2 | 90.4 |
| 8 | 4 | 69.7 | 87.2 |
| 9 | 5 | 70.8 | 84.7 |

It will be readily appreciated by those skilled in the art that modifications may be made to the invention without departing from the concepts disclosed in the foregoing description. Accordingly, the particular embodiments described in detail herein are illustrative only and are not limiting to the scope of the invention, which is to be given the full breadth of the appended claims and any and all equivalent thereof.

The invention claimed is:

1. A solar cell, comprising:
a first substrate having a first surface and a second surface;
a haze coating over at least a portion of the first surface, the haze coating comprising an oxide coating incorporating nanoparticles;
a first conductive layer over at least a portion of the second surface;
a semiconductor layer over the first conductive layer; and
a second conductive layer over at least a portion of the semiconductor layer.

2. The solar cell of claim 1, further comprising an undercoating layer between the second surface and the first conductive layer.

3. The solar cell of claim 1, further comprising a second substrate over the second conductive layer.

4. The solar cell of claim 1, wherein the first substrate is float glass having a tin side and an air side, and the haze coating is over the tin side.

5. The solar cell of claim 1, wherein the haze coating comprises at least one oxide selected from the group consisting of silica, tin oxide, titania, aluminum oxide, zirconium oxide, phosphorous oxide, and mixtures thereof.

6. The solar cell of claim 1, wherein the nanoparticles are selected from the group consisting of titania, indium tin oxide, fluorine tin oxide, silica, alumina, colloidal silica, cerium oxide, and mixtures thereof.

7. The solar cell of claim 1, wherein the first conductive layer comprises oxides of one or more of Zn, Fe, Mn, Al, Ce, Sn, Sb, Hf, Zr, Ni, Zn, Bi, Ti, Co, Cr, Si, or In, or an alloy of two or more of these materials.

8. The solar cell of claim 7, wherein the first conductive layer comprises at least one dopant selected from F, In, Al, P, and Sb.

9. The solar cell of claim 8, wherein the first conductive layer comprises fluorine-doped tin oxide.

10. The solar cell of claim 1, wherein the semiconductor layer is selected from monocrystalline silicon, polycrystalline silicon, amorphous silicon, cadmium telluride, and copper indium celenide/sulfide.

11. The solar cell of claim 1, wherein the second conductive layer is selected from the group consisting of Zn, Fe, Mn, Al, Ce, Sn, Sb, Hf, Zr, Ni, Zn, Bi, Ti, Co, Cr, Si, or In, or an alloy of two or more of these materials.

12. The solar cell of claim 2, wherein the undercoating layer is a multilayer coating comprising a first layer comprising tin oxide or titania, and a second layer comprising a compositional uniform or non-uniform mixture comprising oxides of at least two of Sn, P, Si, Ti, Al, and Zr.

13. A solar cell, comprising:
a first float glass substrate having a tin side and an air side;
a haze coating over at least a portion of the tin side, the haze coating comprising silica incorporating nanoparticles selected from the group consisting of titania, indium tin oxide, fluorine tin oxide, silica, alumina, colloidal silica, cerium oxide, and mixtures thereof;
a first conductive layer over at least a portion of the air side, the first conductive layer comprising oxides of one or more of Sn and In;
a semiconductor layer over the first conductive layer, the semiconductor layer comprising a material selected from the group consisting of monocrystalline silicon, polycrystalline silicon, amorphous silicon, cadmium telluride, and copper indium celenide/sulfide; and
a second conductive layer over at least a portion of the semiconductor layer, the second conductive layer comprising oxides of one or more of Sn and In.

14. The solar cell of claim 13, wherein the first conductive layer comprises fluorine-doped tin oxide.

15. A method of making a solar cell, comprising the steps of:
forming a haze coating over at least a portion of a tin side of a float glass substrate, the haze coating comprising silica incorporating nanoparticles selected from the group consisting of titania, indium tin oxide, fluorine tin oxide, silica, alumina, colloidal silica, cerium oxide, and mixtures thereof;
forming a first conductive layer over at least a portion of an air side of the float glass substrate, the first conductive layer comprising oxides of one or more of Sn and In;
forming a semiconductor layer over the first conductive layer, the semiconductor layer comprising a material selected from the group consisting of monocrystalline silicon, polycrystalline silicon, amorphous silicon, cadmium telluride, and copper indium celenide/sulfide; and
forming a second conductive layer over at least a portion of the semiconductor layer, the second conductive layer comprising oxides of one or more of Sn and In.

16. The method of claim 15, wherein the haze coating is deposited by spray pyrolysis.

17. The method of claim 16, wherein the first conductive layer, the semiconductor layer, and the second conductive layer are deposited using methods selected from the group consisting of CVD and MSVD.

18. The method of claim 15, further including the steps of:
forming the first conductive layer by a method selected from CVD or MSVD;
heating the substrate; and
forming the haze layer by spray pyrolysis.
